(19) United States
(12) Patent Application Publication
(10) Pub. No.: US 2025/0277749 A1
(43) Pub. Date: Sep. 4, 2025

(54) WAFER DETECTION SYSTEM AND METHOD OF MONITORING THE SAME

(71) Applicant: NANYA TECHNOLOGY CORPORATION, New Taipei city (TW)

(72) Inventors: Yi-Wen LIU, New Taipei City (TW); Jih-Cheng HUANG, New Taipei City (TW)

(21) Appl. No.: 18/593,866

(22) Filed: Mar. 2, 2024

(51) Int. Cl. G01N 21/93; G01N 21/88; G01N 21/95

(52) U.S. Cl. CPC G01N 21/93; G01N 21/8806; G01N 21/8851; G01N 21/9505; G01N 2021/8809; G01N 2021/8835; G01N 2021/8867; G01N 2021/8887

(57) ABSTRACT

The present disclosure provides a method of monitoring a wafer detection system. The method includes: capturing an image of a standard wafer exposed to a light source, in which the image of the standard wafer has a standard brightness range, and in which the light source has a luminous power with a maximum limit; adjusting the luminous power of the light source to maintain a brightness of an image of the standard wafer within the standard brightness range as the light source deteriorates; and issuing an alert when the luminous power is equal or greater than a preset value lower than the maximum limit.

### FIELD OF INVENTION

The present invention relates to a wafer detection system and a method of monitoring the same.

### DESCRIPTION OF RELATED ART

Wafer appearance defect detection apparatus can detect wafer-related defects (such as, scratches, cracks, missing corners, particles, discoloration, dirt, indentations, etc.) to replace manual identification operations. However, the quality of wafer images produced by using wafer appearance defect detection apparatus for identifying wafer defects has a huge impact on subsequent process or AI (artificial intelligence) interpretation. Therefore, the stability of image capturing device is even more vital.

The image capturing device includes cameras, lenses, and light sources. It is easier to detect abnormal damage to the cameras or the lenses. On the other hand, the light source has the possibility of deterioration (for example, attenuation), and it is not easy to detect when the light source gradually attenuates over time.

Since the wafer images captured by the wafer appearance defect detection apparatus are imported into AI (artificial intelligence), if the light source attenuation causes poor image quality, a large number of the wafer images will lose their authenticity. In addition, subsequent wafer processing methods are also susceptible to misjudgment, which will have a considerable impact.

Therefore, how to propose a wafer detection system and a method of monitoring the same that can prevent the wafer images from misjudging is one of the problems that the industry urgently wants to invest in research and development resources to solve.

### SUMMARY

In view of this, one purpose of the present disclosure is to provide a wafer detection system and a method of monitoring the same can solve the aforementioned problems.

In order to achieve the above objective, according to an embodiment of the present disclosure, a method of monitoring a wafer detection system includes: capturing an image of a standard wafer exposed to a light source, wherein the image of the standard wafer has a standard brightness range, and wherein the light source has a luminous power with a maximum limit; adjusting the luminous power of the light source to maintain a brightness of an image of the standard wafer within the standard brightness range as the light source deteriorates; and issuing an alert when the luminous power is equal or greater than a preset value lower than the maximum limit.

In one or more embodiments of the present disclosure, adjusting the luminous power of the light source further includes: increasing or decreasing the luminous power to adjust a luminance of the light source when the brightness of the image of the standard wafer is out of the standard brightness range.

In one or more embodiments of the present disclosure, adjusting the luminous power of the light source further includes: increasing the luminous power to increase a luminance of the light source when the brightness of the image of the standard wafer is less than a lower limit of the standard brightness range; and decreasing the luminous power to decrease the luminance of the light source when the brightness of the image of the standard wafer is greater than an upper limit of the standard brightness range.

In one or more embodiments of the present disclosure, capturing the image of the standard wafer exposed to the light source is performed repeatedly and periodically.

In one or more embodiments of the present disclosure, the method further includes collecting data of the luminous power of the light source and data of the brightness of the image of the standard wafer after capturing the image of the standard wafer exposed to the light source.

In one or more embodiments of the present disclosure, the method further includes storing the data of the luminous power of the light source and the data of the brightness of the image of the standard wafer after collecting the data of the luminous power of the light source and the data of the brightness of the image of the standard wafer.

In one or more embodiments of the present disclosure, the method further includes analyzing the data of the luminous power of the light source and the data of the brightness of the image of the standard wafer after collecting the data of the luminous power of the light source and the data of the brightness of the image of the standard wafer.

In one or more embodiments of the present disclosure, the preset value is 80 percent of the maximum limit of the luminous power of the light source.

In order to achieve the above objective, according to an embodiment of the present disclosure, a method of monitoring a wafer detection system includes: capturing a plurality of images of a plurality of standard wafers exposed to a light source, wherein the images of the standard wafers have a standard brightness range, and wherein the light source has a luminous power with a maximum limit; analyzing time-dependent data of the luminous power of the light source to predict a replacement time point; and issuing an alert when the luminous power is equal or greater than a preset value lower than the maximum limit.

In one or more embodiments of the present disclosure, the method further includes adjusting the luminous power of the light source to maintain a brightness of each of the images of the standard wafers within the standard brightness range.

In one or more embodiments of the present disclosure, adjusting the luminous power of the light source further includes: increasing or decreasing the luminous power to adjust a luminance of the light source when the brightness of the images of the standard wafers is out of the standard brightness range.

In one or more embodiments of the present disclosure, adjusting the luminous power of the light source further includes: increasing the luminous power to increase a luminance of the light source when the brightness of the images of the standard wafers is less than a lower limit of the standard brightness range; and decreasing the luminous power to decrease the luminance of the light source when the brightness of the images of the standard wafers is greater than an upper limit of the standard brightness range.

In one or more embodiments of the present disclosure, analyzing the time-dependent data of the luminous power of the light source further includes:

generating a time sequence of the time-dependent data of the luminous power of the light source; and calculating a predicted replacement time point based on the time sequence.

In one or more embodiments of the present disclosure, calculating the predicted replacement time point based on the time sequence is performed by calculating a fitting curve of the time sequence.

In one or more embodiments of the present disclosure, the predicted replacement time point is before a time point when the luminous power of the light source reaches the maximum limit.

In one or more embodiments of the present disclosure, the method further includes storing the time-dependent data of the luminous power of the light source after capturing the images of the standard wafers exposed to the light source.

In order to achieve the above objective, according to an embodiment of the present disclosure, a wafer detection system includes an image capturing device, a light source, and a processing device. The image capturing device is configured to capture an image of a wafer. The image of the wafer has a standard brightness range. The light source is configured to illuminate the wafer. The light source has a luminous power with a maximum limit. The processing device is electrically or communicatively connected to the light source and the image capturing device. The processing device is configured to: adjust the luminous power of the light source to maintain a brightness of the image of the wafer within the standard brightness range; and issuing an alert when the luminous power is equal or greater than a preset value lower than the maximum limit.

In one or more embodiments of the present disclosure, the wafer detection system further includes an alert unit electrically or communicatively connected to the processing device. The alert unit is configured to perform at least one of: sending an abnormal warning message in response to the alert; and sounding an alarm in response to the alert.

In one or more embodiments of the present disclosure, the wafer detection system further includes a database electrically or communicatively connected to the processing device. The database is configured to store data of the luminous power of the light source and data of the brightness of the image of the wafer.

In one or more embodiments of the present disclosure, the processing device is further configured to analyze the data of the luminous power of the light source and the data of the brightness of the image of the wafer.

In summary, in the wafer detection system and the method of monitoring the same of the present disclosure, since the image capturing device repeatedly and periodically captures the images of the standard wafers, the data of the luminous power of the light source can be recorded as a time sequence. In the wafer detection system and the method of monitoring the same of the present disclosure, since the luminous power of the light source is adjusted to maintain the brightness of the images of the standard wafers within the standard brightness range, the effect of maintaining the stability of the authentically of each of the images of the standard wafers can be achieved. In the wafer detection system and the method of monitoring the same of the present disclosure, since the alert is issued when the luminous power of the light source is equal or greater than a preset value, and the preset value is less than the maximum limit of the luminous power of the light source, the processing unit can warn the users of the wafer detection system previously to replace the light source in time, thereby avoiding applying the light source which is already inappropriate in use (for example, the light source attenuates, so that the light source cannot provide enough luminance to illuminate the wafers). In the wafer detection system and the method of monitoring the same of the present disclosure, since the processing device is configured to analyze the time-dependent data of the luminous power of the light source, the processing unit can actively observe the usage and the attenuation trends of the light source, thereby predicting the time point of replacing the light source. Overall, the method of monitoring the wafer detection system of the present disclosure improves the stability of the images of the wafers.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a functional block diagram of a wafer detection system in accordance with an embodiment of the present disclosure;

FIG. 2 is a flow chart of a method of monitoring the wafer detection system in accordance with an embodiment of the present disclosure; and

FIG. 3 is a schematic view of issuing an alert when the luminous power is equal or greater than a preset value lower than the maximum limit in accordance with an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The system may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

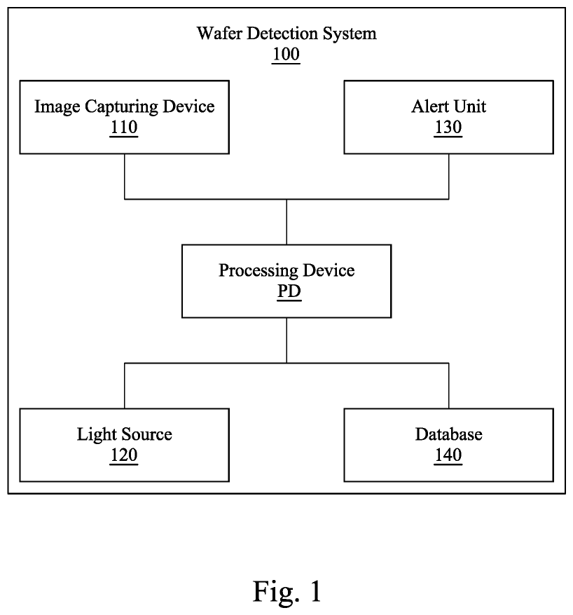

Reference is made to FIG. 1. FIG. 1 is a functional block diagram of a wafer detection system 100 in accordance with an embodiment of the present disclosure. In this embodiment, the wafer detection system 100 includes an image capturing device 110, a light source 120, an alert unit 130, a database 140, and a processing device PD. The image capturing device 110, the light source 120, the alert unit 130, and the database 140 are electrically or communicatively connected to the processing device PD. The image capturing device 110 is configured to capture an image of a wafer. The light source 120 is configured to illuminate the wafer. The alert unit 130 is configured to send an abnormal warning message. The alert unit 130 is further configured to sound an alarm. The database 140 is configured to store data of the luminous power of the light source 120 and data of the brightness of the image of the wafer. The processing device PD is electrically or communicatively connected to the image capturing device 110, the light source 120, the alert unit 130, and the database 140. The processing device PD is configured to adjust a luminous power of the light source 120 to maintain the brightness of the image of the wafer within a standard brightness range. The processing device PD is further configured to issue an alert when the luminous power of the light source 120 is equal or greater than a preset value lower than a maximum limit of the luminous power. In some embodiments, the processing device PD is further configured to permit the alert unit 130 to issue the alert when the luminous power of the light source 120 is equal or greater than the preset value lower than the maximum limit of the luminous power. The processing device PD is further configured to analyze the data of the luminous power of the light source 120 and the data of the brightness of the image of the wafer.

In some embodiments, the wafer may be a standard wafer configured as a standard sample instead of a wafer product. In some embodiments, the wafer may be silicon wafer. In some embodiments, may include a material, such as silicon (Si), polymethylmethacrylate (PMMA), glass, or the like. The present disclosure is not intended to limit the material of the wafer thereto.

In some embodiments, the image capturing device 110 may be camera or any suitable device which is configured to capture an image and record information about the brightness of the image captured by itself. The present disclosure is not intended to limit the type of the image capturing device 110.

In some embodiments, the light source 120 may be light emitting diode (LED) or any suitable light source. The present disclosure is not intended to limit the type of the light source 120.

In some embodiments, the alert unit 130 may include a sounder, such as buzzer, siren, speaker, horn, or the like. In some embodiments, the alert unit 130 may be a display device, such as LED display, liquid crystal display (LCD), organic light emitting diode (OLED) display, quantum light emitting diode (QLED) display, or the like. In some embodiments, the alert unit 130 may send the abnormal warning message in form of, for example, text message, push notification, pop-up window, projection mapping, augmented reality (AR) projection, virtual reality (VR) projection, or the like. In some embodiments, the alert unit 130 may be a combination of the sounder and the display device. The present disclosure is not intended to limit the type of the alert unit 130.

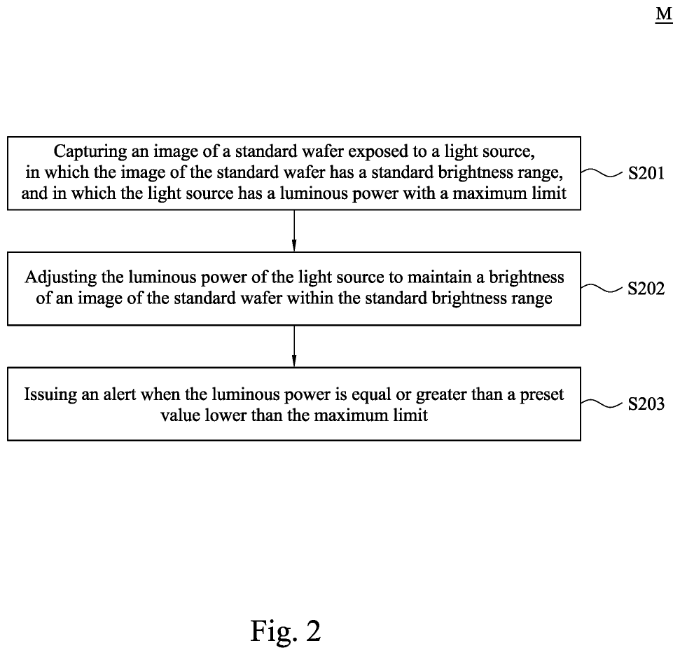

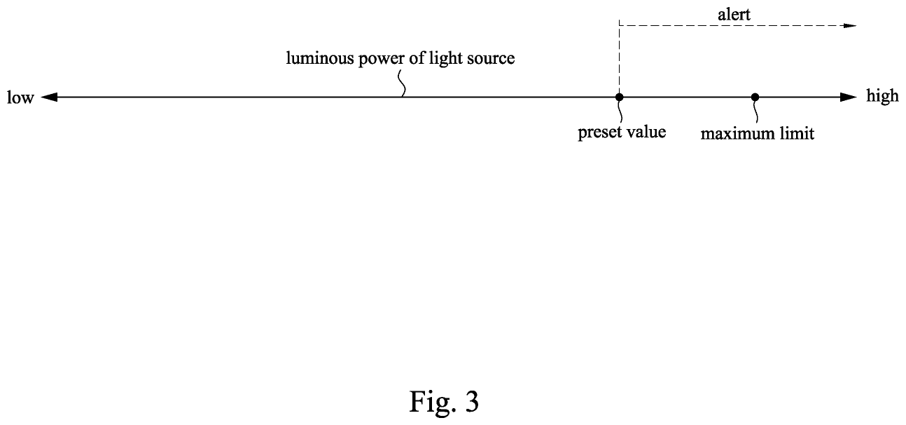

Reference is made to FIG. 2. FIG. 2 is a flow chart of a method M of monitoring the wafer detection system 100 as shown in FIG. 1 in accordance with an embodiment of the present disclosure. The method M shown in FIG. 2 includes a step S201, a step S202, and a step S203. Please refer to FIG. 1 and FIG. 2 for better understanding the step S201 and the step S202 and refer to FIG. 2 and FIG. 3 for better understanding the step S203.

Step S201, step S202, and step S203 are described in detail below.

In step S201, an image of a standard wafer exposed to the light source 120 is captured.

Reference is made to FIG. 1 and FIG. 2. In this embodiment, the image of the standard wafer is captured by the image capturing device 110. More specifically, the standard wafer is exposed to the light source 120, so that the standard wafer is illuminated. Next, the image capturing device 110 captures the image of the standard wafer. In some embodiments, the image of the standard wafer has a brightness. The image of the standard wafer has a standard brightness range. In some embodiments, the image of the standard wafer is defined as a valid image if the brightness of the image of the standard wafer is within the standard brightness range.

In some embodiments, the light source 120 has a luminous power. The luminous power of the light source 120 has a maximum limit.

In some embodiments, the step S201 is performed repeatedly and periodically. In some embodiments, the image capturing device 110 captures a plurality of images of the standard wafer. In some embodiments, the image capturing device 110 captures the image of the standard wafer every week, every day, every hour, every minute, every second, or other suitable period.

In some embodiments, the method M further includes collecting data of the luminous power of the light source 120 and data of the brightness of the image of the standard wafer. In some embodiments, collecting the data of the luminous power of the light source 120 and the data of the brightness of the image of the standard wafer is performed after the step S201. More specifically, the image capturing device 110 captures the image of the standard wafer. Next, the processing device PD collecting the data of the luminous power of the light source 120 and the data of the brightness of the image of the standard wafer from the light source 120 and the image capturing device 110, respectively.

In some embodiments, the method M further includes storing the data of the luminous power of the light source 120 and the data of the brightness of the image of the standard wafer. In some embodiments, storing the data of the luminous power of the light source 120 and the data of the brightness of the image of the standard wafer is performed after the step S201. In some embodiments, storing the data of the luminous power of the light source 120 and the data of the brightness of the image of the standard wafer is performed after collecting the data of the luminous power of the light source 120 and the data of the brightness of the image of the standard wafer. More specifically, the processing device PD collects the data of the luminous power of the light source 120 and the data of the brightness of the image of the standard wafer. Next, the processing device PD stores the data of the luminous power of the light source 120 and the data of the brightness of the image of the standard wafer in the database 140.

In some embodiments, the method M further includes analyzing the data of the luminous power of the light source 120 and the data of the brightness of the image of the standard wafer. In some embodiments, analyzing the data of the luminous power of the light source 120 and the data of the brightness of the image of the standard wafer is performed after the step S201. In some embodiments, analyzing the data of the luminous power of the light source 120 and the data of the brightness of the image of the standard wafer is performed after collecting the data of the luminous power of the light source 120 and the data of the brightness of the image of the standard wafer. More specifically, the database 140 stores the data of the luminous power of the light source 120 and the data of the brightness of the image of the standard wafer. Next, the processing device PD analyzes the data of the luminous power of the light source 120 and the data of the brightness of the image of the wafer.

In some embodiments, the processing device PD analyzes time-dependent data of the luminous power of the light source 120 to predict a replacement time point. In some embodiments, analyzing the time-dependent data of the luminous power of the light source 120 includes generating a time sequence of the time-dependent data of the luminous power of the light source 120. More specifically, the processing device PD analyzes the time-dependent data of the luminous power of the light source 120 and generates the time sequence of the luminous power of the light source 120 depicted as a graph (e.g., a line graph, or the like). In some embodiments, analyzing the time-dependent data of the luminous power of the light source 120 further includes calculating a predicted replacement time point based on the time sequence. More specifically, the processing device PD generates the time sequence of the luminous power of the light source 120 and calculating a mathematical function of a fitting curve of the time sequence. In some embodiments, calculating the predicted replacement time point based on the time sequence is performed by calculating the fitting curve of the time sequence. For instance, the predicted replacement time point is the solution of the mathematical function of the fitting curve of the time sequence. The predicted replacement time point is defined as a time point when the light source 120 needs to be replaced in the future. In some embodiments, the predicted replacement time point is before a time point when the luminous power of the light source 120 reaches the maximum limit.

In step S202, the luminous power of the light source 120 is adjusted to maintain a brightness of the image of the standard wafer within the standard brightness range.

Reference is made again to FIG. 1 and FIG. 2. In this embodiment, the processing device PD adjusts the luminous power of the light source 120. The luminous power of the light source 120 is adjusted by the processing device PD to maintain the brightness of the image of the standard wafer within the standard brightness range. More specifically, adjusting the luminous power of the light source 120 includes increasing or decreasing the luminous power of the light source 120 to adjust a luminance of the light source 120 when the brightness of the image of the standard wafer is out of the standard brightness range. In some embodiments, the standard brightness range has a lower limit and an upper limit.

In a usage scenario, when the brightness of the image of the standard wafer is less than the lower limit of the standard brightness range, the processing device PD increases the luminous power of the light source 120 to increase a luminance of the light source 120. In contrast, when the brightness of the image of the standard wafer is greater than the upper limit of the standard brightness range, the processing device PD decreases the luminous power of the light source 120 to decrease the luminance of the light source 120.

In a usage scenario, when the brightness of the image of the standard wafer is greater than the lower limit of the standard brightness range and lower than the upper limit of the standard brightness range, the processing device PD does not adjust the luminous power of the light source 120 to maintain the luminance of the light source 120.

In some embodiments, the light source 120 deteriorates over time. More specifically, the luminous power of the light source 120 needs to be adjusted greater to maintain the luminance to the same extent as the light source 120 deteriorates. In a practical scenario, the brightness of the image of the standard wafer may be less than the lower limit of the standard brightness range even though the luminous power of the light source 120 is adjusted to reach the maximum limit as the light source 120 deteriorates.

In step S203, an alert is issued when the luminous power is equal or greater than a preset value lower than the maximum limit.

Reference is made to FIG. 2 and FIG. 3. FIG. 3 is a schematic view of issuing an alert when the luminous power is equal or greater than a preset value lower than the maximum limit in accordance with an embodiment of the present disclosure. In this embodiment, the alert unit 130 issues an alert based on the luminous power of the light source 120. In some embodiments, the processing device PD issues the alert by the alert unit 130. The process device PD or the alert unit 130 issues the alert when the luminous power is equal or greater than a preset value. In some embodiments, the preset value is lower than the maximum limit of the luminous power of the light source 120. This ensures the light source 120 can be replaced before the processing device PD is not able to maintain the brightness of the image of the standard wafer within the standard brightness range.

As shown in FIG. 3, the luminous power of the light source 120 is shown in form of a left right arrow. As shown in FIG. 3, the preset value is lower than the maximum limit. In this embodiment, the alert is issued when the luminous power of the light source 120 is equal or greater than the preset value which is lower than the maximum limit.

In some embodiments, the preset value is about 80 percent of the maximum limit of the luminous power of the light source 120. However, the present disclosure is not intended to limit the preset value set relative to the maximum limit of the luminous power of the light source 120.

In some embodiments in which the preset value is 80 percent of the maximum limit of the luminous power of the light source 120, when the luminous power of the light source 120 reaches 80 percent of the maximum limit of the luminous power of the light source 120, the alert unit 130 sends the abnormal warning message in response to the alert. In some embodiments in which the preset value is 80 percent of the maximum limit of the luminous power of the light source 120, when the luminous power of the light source 120 reaches 80 percent of the maximum limit of the luminous power of the light source 120, the alert unit 130 sounds an alarm in response to the alert.

In a usage scenario, when a user is aware of the alert, the user can shut down the wafer detection system 100 beforehand to replace the light source 120 with a new light source 120. This ensures the light source 120 remains available at all time, thereby improving the stability and authenticity of the image of the standard wafer. Furthermore, the user can obtain a longer grace period to await a delivery of the new light source 120.

By performing the method M shown in FIG. 2 of the present disclosure, the images of the wafers with better stability and authenticity may be provided.

Based on the above discussions, it can be seen that in the wafer detection system and the method of monitoring the same of the present disclosure, since the image capturing device repeatedly and periodically captures the images of the standard wafers, the data of the luminous power of the light source can be recorded as a time sequence. In the wafer detection system and the method of monitoring the same of the present disclosure, since the luminous power of the light source is adjusted to maintain the brightness of the images of the standard wafers within the standard brightness range, the effect of maintaining the stability of the authentically of each of the images of the standard wafers can be achieved. In the wafer detection system and the method of monitoring the same of the present disclosure, since the alert is issued when the luminous power of the light source is equal or greater than a preset value, and the preset value is less than the maximum limit of the luminous power of the light source, the processing unit can warn the users of the wafer detection system previously to replace the light source in time, thereby avoiding applying the light source which is already inappropriate in use (for example, the light source attenuates, so that the light source cannot provide enough luminance to illuminate the wafers). In the wafer detection system and the method of monitoring the same of the present disclosure, since the processing device is configured to analyze the time-dependent data of the luminous power of the light source, the processing unit can actively observe the usage and the attenuation trends of the light source, thereby predicting the time point of replacing the light source. Overall, the method of monitoring the wafer detection system of the present disclosure improves the stability of the images of the wafers.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of monitoring a wafer detection system, comprising:
capturing an image of a standard wafer exposed to a light source, wherein the image of the standard wafer has a standard brightness range, and wherein the light source has a luminous power with a maximum limit;
adjusting the luminous power of the light source to maintain a brightness of the image of the standard wafer within the standard brightness range as the light source deteriorates; and
issuing an alert when the luminous power is equal or greater than a preset value lower than the maximum limit.

2. The method of claim 1, wherein adjusting the luminous power of the light source further comprises:
increasing or decreasing the luminous power to adjust a luminance of the light source when the brightness of the image of the standard wafer is out of the standard brightness range.

3. The method of claim 1, wherein adjusting the luminous power of the light source further comprises:
increasing the luminous power to increase a luminance of the light source when the brightness of the image of the standard wafer is less than a lower limit of the standard brightness range; and
decreasing the luminous power to decrease the luminance of the light source when the brightness of the image of the standard wafer is greater than an upper limit of the standard brightness range.

4. The method of claim 1, wherein capturing the image of the standard wafer exposed to the light source is performed repeatedly and periodically.

5. The method of claim 1, further comprising collecting data of the luminous power of the light source and data of the brightness of the image of the standard wafer after capturing the image of the standard wafer exposed to the light source.

6. The method of claim 5, further comprising storing the data of the luminous power of the light source and the data of the brightness of the image of the standard wafer after collecting the data of the luminous power of the light source and the data of the brightness of the image of the standard wafer.

7. The method of claim 5, further comprising analyzing the data of the luminous power of the light source and the data of the brightness of the image of the standard wafer after collecting the data of the luminous power of the light source and the data of the brightness of the image of the standard wafer.

8. The method of claim 1, wherein the preset value is 80 percent of the maximum limit of the luminous power of the light source.

9. A method of monitoring a wafer detection system, comprising:
capturing a plurality of images of a plurality of standard wafers exposed to a light source, wherein the images of the standard wafers have a standard brightness range, and wherein the light source has a luminous power with a maximum limit;
analyzing time-dependent data of the luminous power of the light source to predict a replacement time point; and
issuing an alert when the luminous power is equal or greater than a preset value lower than the maximum limit.

10. The method of claim 9, further comprising adjusting the luminous power of the light source to maintain a brightness of each of the images of the standard wafers within the standard brightness range.

11. The method of claim 10, wherein adjusting the luminous power of the light source further comprises:
increasing or decreasing the luminous power to adjust a luminance of the light source when the brightness of the images of the standard wafers is out of the standard brightness range.

12. The method of claim 10, wherein adjusting the luminous power of the light source further comprises:
increasing the luminous power to increase a luminance of the light source when the brightness of the images of the standard wafers is less than a lower limit of the standard brightness range; and
decreasing the luminous power to decrease the luminance of the light source when the brightness of the images of the standard wafers is greater than an upper limit of the standard brightness range.

13. The method of claim 9, wherein analyzing the time-dependent data of the luminous power of the light source further comprises:
generating a time sequence of the time-dependent data of the luminous power of the light source; and
calculating a predicted replacement time point based on the time sequence.

14. The method of claim 13, wherein calculating the predicted replacement time point based on the time sequence is performed by calculating a fitting curve of the time sequence.

15. The method of claim 13, wherein the predicted replacement time point is before a time point when the luminous power of the light source reaches the maximum limit.

16. The method of claim 9, further comprising storing the time-dependent data of the luminous power of the light source after capturing the images of the standard wafers exposed to the light source.

17. A wafer detection system, comprising:
an image capturing device configured to capture an image of a wafer, wherein the image of the wafer has a standard brightness range;
a light source configured to illuminate the wafer, wherein the light source has a luminous power with a maximum limit; and
a processing device electrically or communicatively connected to the light source and the image capturing device, wherein the processing device is configured to:
adjust the luminous power of the light source to maintain a brightness of the image of the wafer within the standard brightness range; and
issuing an alert when the luminous power is equal or greater than a preset value lower than the maximum limit.

18. The wafer detection system of claim 17, further comprising an alert unit electrically or communicatively connected to the processing device, wherein the alert unit is configured to perform at least one of:
sending an abnormal warning message in response to the alert; and
sounding an alarm in response to the alert.

19. The wafer detection system of claim 17, further comprising a database electrically or communicatively connected to the processing device, wherein the database is configured to store data of the luminous power of the light source and data of the brightness of the image of the wafer.

20. The wafer detection system of claim 19, wherein the processing device is further configured to analyze the data of the luminous power of the light source and the data of the brightness of the image of the wafer.
